(19) United States
(12) Patent Application Publication
(10) Pub. No.: US 2021/0118716 A1
(43) Pub. Date: Apr. 22, 2021

(54) ELECTROSTATIC CHUCK, METHOD OF MANUFACTURING ELECTROSTATIC CHUCK, AND PLASMA PROCESSING APPARATUS

(71) Applicant: ADVANCED MICRO-FABRICATION EQUIPMENT INC. CHINA, Shanghai (CN)

(72) Inventors: Rubin YE, Shanghai (CN); Leyi TU, Shanghai (CN); Tuqiang NI, Shanghai (CN); Jie LIANG, Shanghai (CN); Manus WONG, Shanghai (CN); Hanyi ZHAO, Shanghai (CN); Dee WU, Shanghai (CN)

(21) Appl. No.: 17/070,735

(22) Filed: Oct. 14, 2020

(30) Foreign Application Priority Data
Oct. 18, 2019 (CN) 201910996040.9

(51) Int. Cl. H01L 21/683; H01L 21/67; H01J 37/32

(52) U.S. Cl. CPC H01L 21/6833; H01L 21/67109; H01J 37/32715; H01J 2237/334; H01L 21/67069; H01J 2237/2007; H01J 37/32568

(57) ABSTRACT

Disclosed is an electrostatic chuck, including a base and a disc structure disposed on the base, the upper surface of the disc structure being configured for holding a wafer, wherein a first through-hole is formed in the base, a shunt part is provided in the first through-hole to partition the first through-hole into a plurality of sub-through-holes, and a filled layer is formed between the shunt part and a sidewall of the first through-hole; and a second through-hole is provided in and axially penetrating through the disc structure, the diameter of the first through-hole being greater than the diameter of the second through-hole, the second through-hole communicating with the first through-hole.

### RELATED APPLICATION

The present application claims priority to and the benefit of Chinese Patent Application No. 201910996040.9 filed on Oct. 18, 2019, and the disclosure of which is hereby incorporated by reference in its entirety.

### FIELD

Embodiments of the present disclosure generally relate to semiconductor devices and manufacturing of the same, and more particularly relate to an electrostatic chuck, a method of manufacturing the electrostatic chuck, and a plasma processing apparatus.

### BACKGROUND

Among various procedures of semiconductor device fabrication, plasma processing is a key procedure to process a wafer into a designed pattern. In typical plasma processing, a process gas is excited by radio frequency (RF) to form plasma. Such plasma, after being subjected to the electric field (capacitively coupled or inductively coupled) between the upper electrode and the lower electrode, experiences physical bombardment and chemical reaction with the wafer surface so as to process the wafer.

An electrostatic chuck (ESC) serves as a support platform for the wafer and meanwhile serves to regulate temperature of the wafer disposed thereon. A cooling device may be provided for the electrostatic chuck to cool the wafer during processing, thereby maintaining the wafer temperature within a certain range. Pores may be provided for the electrostatic chuck; as such, the cooling gas in the cooling device flows via the pores towards the backside of the wafer to absorb wafer heat, thereby cooling the wafer. The diameters and positions of the pores in the electrostatic chuck have an impact on value and homogeneity of wafer temperature.

With advancement of 3D storage technologies, a higher wafer temperature and a higher RF power are usually called for when using plasma to process the wafer on the electrostatic chuck, while the high temperature and high power tends to break down the cooling gas in the pores to incur arcing. In serious circumstances, arcing causes damages to the wafer and the electrostatic chuck, even permanently damaging the electrostatic chuck.

An electrostatic chuck capable of lowering odds of occurrence of arc discharge is thus provided.

### SUMMARY

Embodiments of the present disclosure provide an electrostatic chuck, comprising:

a base, wherein a first through-hole is formed in the base, a shunt part is provided in the first through-hole to partition the first through-hole into a plurality of sub-through-holes, and a filled layer is formed between the shunt part and a sidewall of the first through-hole; and

a disc structure disposed on the base, wherein an upper surface of the disc structure is configured to hold the wafer, and a second through-hole is provided in and axially penetrating through the disc structure, the second through-hole communicating with the first through-hole.

Optionally, the filled layer is made of a material selected from at least one of ceramic, epoxy, and silicon resin.

Optionally, the filled layer covers the upper edge and/or lower edge of the shunt part.

Optionally, a first countersink is formed in a surface of the filled layer covering the upper edge of the shunt part, the surface of the filled layer facing towards the first through-hole.

Optionally, the disc structure and the base are bonded via an adhesive layer, the filled layer and the adhesive layer being made of a same material, an isolation layer being formed between the shunt part and the filled layer.

Optionally, an interlayer gap is provided between the shunt structure and the disc structure, the distance between the filled layer and the disc structure being smaller than the interlayer gap.

Optionally, a second countersink is formed in a surface of the disc structure, the surface of the disc structure facing towards the base, and the shunt part extending into the second countersink.

Optionally, the second through-hole comprises a plurality of sub-through-holes.

Optionally, the plurality of sub-through-holes are formed by fabricating a porous structure in the second through-hole, or are formed by etching the disc structure.

Optionally, after the base is powered up, an electric field line is present between the wafer on the disc structure and the base, and the directions of the plurality of sub-through-holes not located in the center of the second through-hole are vertical to the direction of the electric field line.

Optionally, a chamfering is formed at the upper opening of the first through-hole, and a dielectric layer is provided between the base and the adhesive layer bonding the base and the disc structure, the dielectric layer covering the chambering.

Optionally, the shunt structure refers to a porous plug.

Embodiments of the present disclosure provide a method of manufacturing an electrostatic chuck, comprising:

forming a first through-hole in a base;

forming a shunt part in the first through-hole to partition the first through-hole into a plurality of sub-through-holes, a filled layer being formed between the shunt part and a sidewall of the first through-hole; and

providing a disc structure on the base, wherein an upper surface of the disc structure is configured to hold the wafer; and a second through-hole is provided in and axially penetrating through the disc structure, the second through-hole communicating with the first through-hole.

Optionally, the forming a shunt part in the first through-hole comprises:

disposing the shunt part in the first through-hole, an isolation layer being formed on the outer wall of the shunt part;

filling up between the shunt part and the sidewall of the first through-hole to form the filled layer, and forming an adhesive layer at a position of the base where the first through-hole is not formed, the adhesive layer being configured to bond the base and the disc structure, the filled material and the adhesive layer being made of a same material.

Optionally, the forming a shunt part in the first through-hole comprises:

disposing the shunt part in the filled layer, wherein the filled layer is made of a material selected from at least one of ceramic, epoxy, and silicon resin; and

disposing, in the first through-hole, the filled layer enclosing the shunt part.

Optionally, the filled layer is made of a material selected from at least one ceramic, epoxy, and silicon resin.

Optionally, the filled layer covers an upper edge and/or lower edge of the shunt part.

Optionally, a first countersink is formed in a surface of the filled layer covering the upper edge of the shunt part, the surface of the filled layer facing towards the first through-hole.

Optionally, an interlayer gap is provided between the shunt structure and the disc structure, the distance between the filled layer and the disc structure being smaller than the interlayer gap.

Optionally, a second countersink is formed in a surface of the disc structure, the surface of the disc structure facing towards the base, and the shunt part extending into the second countersink.

Optionally, the second through-hole comprises a plurality of sub-through-holes.

Optionally, the plurality of sub-through-holes are formed by fabricating a porous structure in the second through-hole, or are formed by etching the disc structure.

Optionally, after the base is powered up, an electric field line is present between the wafer on the disc structure and the base, the directions of the plurality of sub-through-holes not located in the center of the second through-hole are vertical to the direction of the electric field line.

Optionally, a chamfer is formed at the upper opening of the first through-hole, and a dielectric layer is provided between the base and the adhesive layer bonding the base and the disc structure, the dielectric layer covering the chambering.

Optionally, the shunt structure refers to a porous plug.

Embodiments of the present disclosure further provide a plasma processing apparatus, comprising an upper electrode and the electrostatic chuck stated above.

Embodiments of the present disclosure provide an electrostatic chuck, comprising a base and a disc structure disposed on the base, the upper surface of the disc structure being configured to hold a wafer. A first through-hole is formed in the base. A shunt part is formed in the first through-hole to partition the first through-hole into a plurality of sub-through-holes. A filled layer is formed between the shunt part and the sidewall of the first through-hole. A second through-hole is provided in and axially penetrating through the disc structure, the first through-hole communicating with the second through-hole. With such configurations, a cooling gas is enabled to pass through the plurality of sub-through-holes in the first through-hole to the second through-hole, thereby accessing the wafer held on the disc structure to regulate wafer temperature. The filled layer is configurable to fill the sidewall gap between the shunt part and the base, preventing the cooling gas in the first through-hole and the second through-hole from accessing the sidewall gap, which reduces the discharge space for the cooling gas, lowers the odds of breaking down the cooling gas, and enhances service life of the electrostatic chuck.

### BRIEF DESCRIPTION OF THE ACCOMPANYING DRAWINGS

Hereinafter, a brief introduction of the drawings is provided for elucidating the embodiments of the present disclosure more clearly. It is apparent that the drawings as illustrated relate only to some embodiments of the present disclosure. To those skilled in the art, other drawings may be obtained based on these drawings without inventive efforts, wherein:

FIG. 1 is a sectional structural schematic diagram of a plasma processing apparatus according to an embodiment of the present disclosure;

FIG. 2-14 are structural schematic diagrams of an electrostatic chuck according to an embodiment of the present disclosure;

FIG. 15 is a flow diagram of a method of manufacturing an electrostatic chuck according to an embodiment of the present disclosure.

### DETAILED DESCRIPTION

To make the technical solutions, features, and advantages of the present disclosure more apparent and comprehensible, illustrative implementations of the present disclosure will be described in detail with reference to the accompanying drawings.

Although detailed implementation manners are provided below for sufficient understanding of the present disclosure, the present disclosure may also be implemented with other manners not described herein, and those skilled in the art may make similar extensions without departing from the scope of the present disclosure; therefore, the present disclosure is not limited to the embodiments disclosed below.

Further, the present disclosure is illustrated in detail with reference to the schematic diagrams; to facilitate illustration, the sectional views representing device structures are not locally enlarged in scales; therefore, the schematic diagrams are only illustrative, which are not intended to limit the protection scope of the present disclosure. Additionally, actual fabrication of such devices shall include three dimensions, i.e., length, width, and depth.

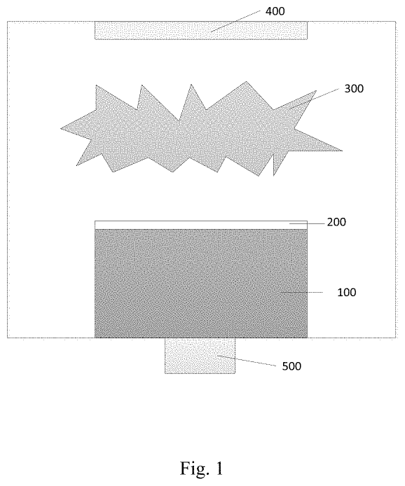

As stated in the background, the wafer may be subjected to a plasma etching process in the plasma etching chamber. FIG. 1 shows a simplified cross-section view of a plasma processing apparatus in the plasma etching chamber, wherein the electrostatic chuck 100 is configurable as a supporting table for a wafer 200 and meanwhile as a lower electrode in the reaction chamber. The plasma etching chamber further comprises an upper electrode 400 corresponding to the electrostatic chuck 100. A gap is present between the upper electrode 400 and the electrostatic chuck 100. Plasma 300 is also generated therebetween. The plasma 300 is adaptable to process the wafer 200 held on the electrostatic chuck 100 in the electric field between the upper electrode 400 and the electrostatic chuck 100.

In some embodiments, the electrostatic chuck 100 is further adaptable to regulate the temperature of the wafer 200 held thereon. In some embodiments, pores are provided in the electrostatic chuck 100. The electrostatic chuck 100 is connected to a cooling device 500. A cooling gas in the cooling device 500 flows via the pores towards the backside of the wafer 200 to absorb the heat of the wafer 200, thereby cooling the wafer 200. With continuous improvement of wafer processing precision, the radio-frequency power applied to the electrostatic chuck 100 becomes increasingly high. In the radio-frequency electric field with such high power, the cooling gas in the pores easily incurs arcing, while the arcing easily causes damages to the electrostatic chuck 100.

On this basis, embodiments of the present disclosure provide an electrostatic chuck, comprising a base and a disc structure disposed on the base, the upper surface of the disc structure being configured to hold a wafer. A first through-hole is formed in the base, and a shunt part is formed in the first through-hole, the shunt part partitioning the first through-hole into a plurality of sub-through-holes. A filled layer is formed between the shunt part and the sidewall of the first through-hole. A second through-hole is provided in and axially penetrating through the disc structure, the first through-hole communicating with the second through-hole. In some embodiments, a cooling gas flows through the plurality of sub-through-holes in the first through-hole towards the second through-hole to access the wafer held on the disc structure, thereby regulating wafer temperature. In some embodiments, the filled layer fills up the sidewall gap between the shunt part and the base, thereby preventing the cooling gas in the first through-hole and the second through-hole from accessing the sidewall gap, which reduces the discharge space for the cooling gas, lowers the odds of breaking down the cooling gas, and enhances service life of the electrostatic chuck.

To better understand the technical solutions and technical effects of the present disclosure, illustrative embodiments of the present disclosure will be described in detail with reference to the accompanying drawings.

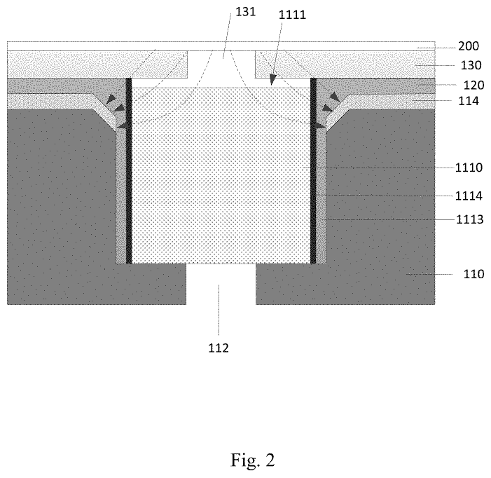

FIG. 2 shows a sectional structural diagram of an electrostatic chuck according to an embodiment of the present disclosure. The electrostatic chuck 100 is disposed in a plasma etching apparatus to hold a wafer 200. The electrostatic chuck 100 comprises a base 110 and a disc structure 130 disposed on the base 110.

In some embodiments of the present disclosure, the base 110 is made of a metal material, such as aluminum and stainless steel. A high frequency (e.g., 400 kHz˜100 mHz) power is applied to the base 110, enabling the base 100 to function as a lower electrode. Opposite the base is an upper electrode 400 disposed at the upper portion of the electrostatic chuck. A voltage difference is created between the upper electrode 400 and the lower electrode, such that the plasma between the upper electrode 400 and the lower electrode moves under the effect of the electric field to act on the wafer 200 held on the electrostatic chuck. Although FIG. 1 illustrates a capacitively coupled plasma processing apparatus, the electrostatic chuck according to the present disclosure is also applicable for an inductively coupled plasma processing apparatus.

The disc structure 130 in the electrostatic chuck is configured to hold the wafer 200. In some embodiments, the disc structure 130 is of a ceramic structure. An electrostatic electrode plate (not shown) is provided in the disc structure 130, such that in the case of applying a positive DC voltage to the electrostatic electrode plate, the electric field generated by the electrostatic electrode plate polarizes the wafer 200 held on the disc structure 130. To neutralize the charges generated by the wafer 200, a negative potential is applied on the surface of the wafer 200. With the coulomb force generated between the potentials of different polarities, the wafer 200 is attachable to the disc structure 130.

After the high-frequency power for the base 110 is raised, a potential difference occurs between the base 110 and the wafer 200. With development of 3D storage technologies, a higher wafer temperature and a higher RF power are called for in circumstances of plasma processing the wafer 200 on the electrostatic chuck; as such, a high radio-frequency power is exerted on the internal components of the base 110. The high radio-frequency power easily incurs arcing inside the base to damage the electrostatic chuck.

In some embodiments, a dielectric layer 114 is formed on the base 110. The dielectric layer 114 is adapted to protect the base 110 and block direct arcing damages between the base 110 and the wafer 200. The dielectric layer 114 is optionally made of aluminum oxide, the thickness of which ranges from 100 μm˜500 μm. In some embodiments, the base 110 and the disc structure 130 are bonded via an adhesive layer 120. The adhesive layer 120 is formed above the dielectric layer 114, with a thickness ranging from 0.1 mm to 0.3 mm.

To implement temperature regulation with respect to the wafer 200 on the electrostatic chuck, a first through-hole 111 is formed in the base 110. The first-through hole 111 is optionally circular, or of other shapes. In one embodiment, one first through-hole 111 is provided; in an alternative embodiment, a plurality of first through-holes are provided. A chamfering is alternatively formed at the upper opening of the first through-hole 111. In the presence of the dielectric layer 114 on the base 110, the dielectric layer 114 covers the upper surface of the chamfering and the base 110 where the first through-hole 111 is not provided. In some embodiments, a second through-hole 131 is provided in and axially penetrating through the disc structure 130. The second through-hole 131 communicates with the first through-hole 111. The second-through hole 111 is optionally circular, or of other shapes. In one embodiment, one second through-hole 111 is provided; in an alternative embodiment, a plurality of first second-holes are provided. As an example, the diameter of the second through-hole 131 ranges from 0.1 mm to 1 mm.

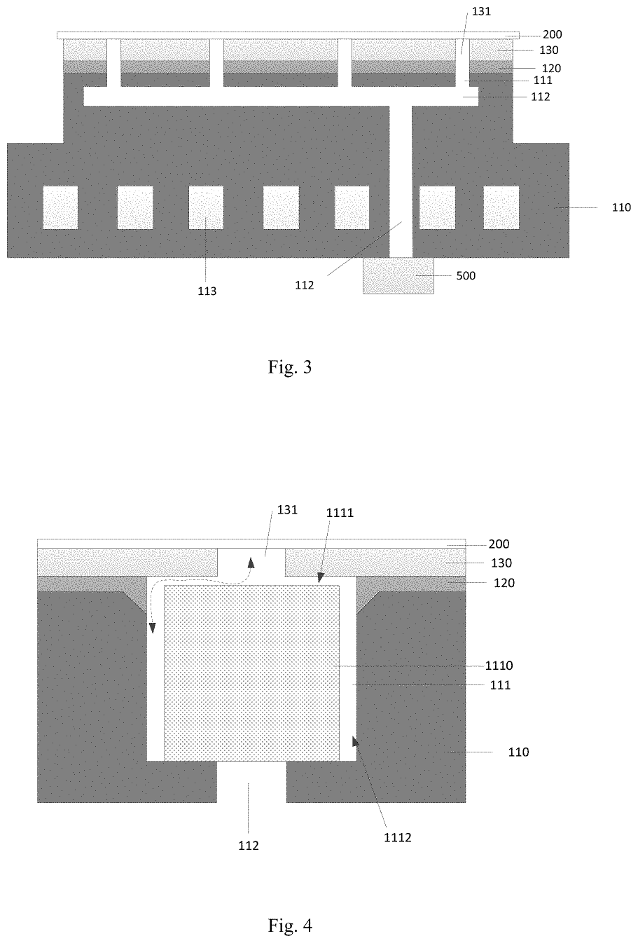

The first through-hole 111 is configured to inlet a cooling gas. In some embodiments, the cooling gas accesses the backside of the wafer 200 via the first through-hole 111 and the second through-hole 131. FIG. 3 illustrates a sectional structural diagram of an electrostatic chuck 100 according to an embodiment of the present disclosure, wherein the first through-hole 111 is connected to the cooling device 500 via a passageway 112, the first through-hole 111 communicating with the second through-hole 131. In this way, the cooling gas enters the second through-hole 131 via the cooling device, the passageway 112, and the first through-hole 111 and then accesses the wafer 200 held on the disc structure 130, thereby enabling control of wafer temperature.

It is understood that the conditions for gas breakdown optionally include: (1) the voltage difference is greater than the voltage threshold for breaking down the cooling gas; (2) the discharge space is large enough, i.e., the discharge space is far larger than the mean free path of the cooling gas, thereby satisfying arcing continuity. In other words, arcing easily occurs in the cases of large enough voltage difference between the wafer 200 and the base 110 and large enough discharge space for the cooling gas. Different cooling gases have different mean free paths under different gas pressures, and a gas with a larger mean free path corresponds to a larger discharge space. Table 1 below lists mean free paths of common gases under different gas pressures.

TABLE 1
Mean Free Paths of Common Gases Under Different
Gas Pressures

| | Mean free paths (um) | | |
|---|---|---|---|
| Gas Type | 10 Torr | 20 Torr | 30 Torr |
| Air | 5.0 | 2.5 | 1.7 |
| Ar | 4.8 | 2.4 | 1.6 |
| He | 13.1 | 6.6 | 4.4 |

It is seen from the table that under the same gas pressure, the gas He has a larger mean free path, such that He requires a larger discharge space to incur arcing. Besides, the gas He has a large joule heat and thus offers a stronger cooling capacity for a unit gas volume, which is thus widely applied as cooling gas.

In practice, the minimum breakdown voltage Vb of a gas satisfies Paschen curve (PD curve), the minimum breakdown voltage Vb being expressed below:

$${V}_{b} = \frac{B \cdot p \cdot d}{ln ( A \cdot p \cdot d ) - ln ( ln ( 1 + \frac{1}{{γ}_{SE}} ) )} ,$$

where A and B are gas type-related constants, p denotes gas pressure, d denotes inter-electrode interval (i.e., effective discharge space), and γ_{SE} denotes a secondary discharge constant of the gas.

Experiments show that under the same breakdown voltage, the gas He has a larger pd value, indicating that with He as the cooling gas, a larger pressure and a larger discharge space may be set. Hereinafter, illustrations will be made as to improvement of the electrostatic chuck, wherein He is taken as an example of cooling gas. However, the present application is not limited thereto. Those skilled in the art may adapt, based on the same idea, parameters of the electrostatic chuck in the case of another cooling gas.

In some embodiments of the present disclosure, a shunt part 1110 is formed in the first through-hole 111 so as to reduce the discharge space in the electrostatic chuck. FIG. 4 shows a sectional structural view of the electrostatic chuck according to an embodiment of the present disclosure, where illustrations will be made with one first through-hole 111 and one second through-hole 131 in FIG. 3. In this embodiment, the shunt part 1110 partitions the first through-hole 111 into a plurality of sub-through-holes, such that the discharge space for the cooling gas in the first through-hole 111 is partitioned into a plurality of smaller spaces, significantly lowering the odds of the cooling gas to incur arcing in the first through-hole 111. In some embodiments, the shunt part 1110 is a porous plug (or a porous ceramic) made of such as aluminum oxide or aluminum nitride, etc.; the sub-through-holes in the porous plug are optionally straight passageways or curved passageways. In the case of curved passageways, the number of times of collisions between the gas and the porous plug sidewall increases, further reducing the discharge space. In some embodiments, the diameter of the sub-through-holes in the porous plug ranges from 1 μm to 300 μm, wherein the volume of the sub-through-holes takes up 20˜70% of the porous plug. In alternative embodiments, the volume of the sub-through-holes takes up 20˜70% of the porous plug.

In the embodiments of the present disclosure, the diameter of the first through-hole 111 is optionally identical to or different from the diameter of the second through-hole 121. For example, in some embodiments, the diameter of the first through-hole 111 is smaller than the diameter of the second through-hole 131; and in alternative embodiments, the diameter of the first through-hole 111 is larger than the diameter of the second through-hole 131. In some embodiments, an interlayer gap 1111 is provided between the shunt structure 1110 and the disc structure 130; as such, the sub-through-holes, which are not arranged opposite the second through-hole 131, in the first through-hole 111 communicate with the second through-hole 131 via the interlayer gap 111. In some embodiments, the diameter of the interlayer gap 1111 depends on the gas flow of and the discharge space for the cooling gas; in the case of He as the cooling gas, the diameter of the interlayer gap 1111 ranges from about 0.1 mm to about 0.3 mm. Of course, the interlayer gap is optionally not provided between the shunt structure 1110 and the disc structure 130; as such, only the sub-through-holes of the first through-hole 111 which are arranged opposite the second through-hole 131 communicate with the second through-hole 131 via the interlayer gap 111.

However, in machining of the base 110 and the shunt part 1110, a sidewall gap 1112 is provided between the shunt part 1110 and the sidewall of the first through-hole 111; as such, a fraction of the cooling gas in the first through-hole likely flows into the sidewall gap 1112 between the shunt part 1110 and the sidewall of the first through-hole 111, which enlarges the discharge space for the cooling gas. In the case that the voltage difference applied to the base 110 is relatively large, the odds of breaking down the cooling gas significantly increases and the electrostatic chuck is very easily damaged by the arcing. In some embodiments, in the presence of the interlayer gap 1111 between the shunt part 1110 and the disc structure 130, the gas in the shunt part 1110 likely flows into the sidewall gap 1112 via the interlayer gap 1111, equivalent to filling-up of the cooling gas between the wafer 200 and the base 110. As indicated by the direction of the dotted line in FIG. 4, the discharge space for the cooling gas is significantly enlarged, which correspondingly increases the odds of breaking down the cooling gas.

Therefore, in an embodiment of the present disclosure, a filled layer 1113 is formed between the shunt part 1110 and the sidewall of the first through-hole 111 to fill up the sidewall interface 1112, thereby preventing entry of the cooling gas into the sidewall gap 1112; such entry would otherwise enlarge the discharge space for the cooling gas, while the enlargement easily incurs arcing.

As an alternative embodiment, the material for the filled layer 1113 is identical to that for the adhesive layer 120; as such, after the shunt part 1110 is disposed in the first through-hole 111, the filled layer 1113 is provided around the shunt part 1110, and at the same time, the adhesive layer 120 is formed on the base, as shown in FIG. 2. It is noted that in the case that the filled layer 1113 and the adhesive layer 120 are made of the same material, the filled layer 113 is fluid. To prevent diffusion of the material of the filled layer 1113 into the shunt part 1110, an isolation layer 1114 is optionally pre-formed on the sidewall of the shunt part 1110, preventing diffusion of the material of the filled layer 1113 into the shunt part 1110; such diffusion would otherwise suppress or block flow of the cooling gas. The material of the isolation layer optionally selects an organic dielectric layer such as a polyimide adhesive tape; the thickness of the isolation layer 1114 is about 50 μm.

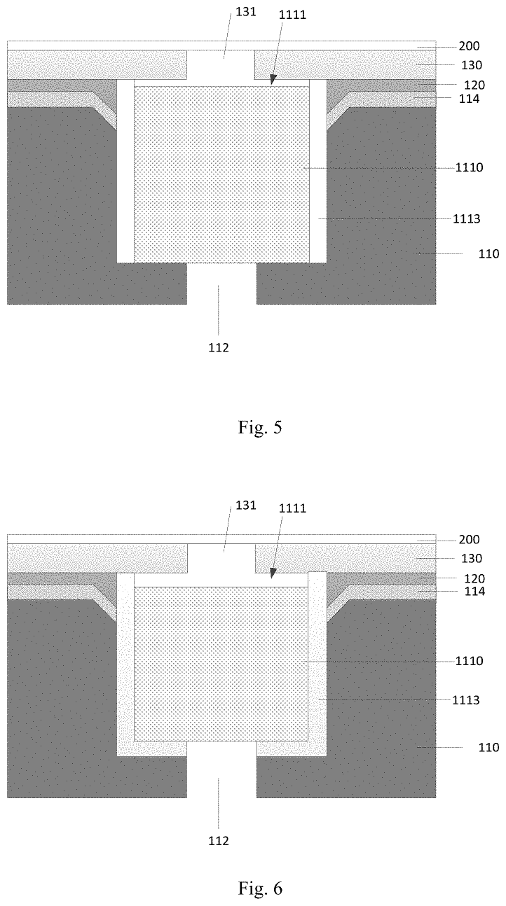

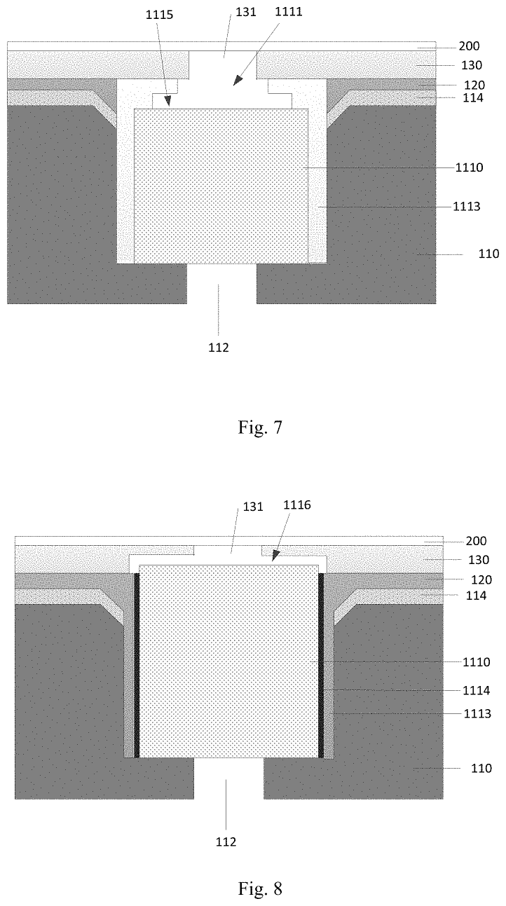

As an alternative embodiment, the material of the filled layer 1113 is selected from at least one of ceramics, epoxy, and silicon resin. As shown in FIG. 5, FIG. 6, and FIG. 7, the filled layer 1113 and the shunt part 1110 are optionally connected by sintering; or, the shunt part 1110 is disposed into and contacts with the filled layer. The gap between the filled layer 1113 and the disc structure 130 is smaller than the interlayer gap 1111 between the shunt part and the disc structure 130. In some embodiments, the filled layer 1113 contacts with the lower surface of the disc structure 130. In some embodiments, the filled layer 1113 fills up the sidewall gap 1112 to prevent the cooling gas from entering the sidewall gap 1112, block the arcing damage path, and meanwhile prevent the adhesive layer 120 from diffusion into the shunt part 1110; such diffusion would otherwise suppress or block flow of the cooling gas.

During the process, a cleaning procedure follows wafer processing, i.e., Waferless Auto Clean (WAC) procedure. During this procedure, the upper surface of the disc structure 130 is exposed to cleaning plasma. Part of the plasma inevitably accesses the second through-hole and the first through-hole. The filled layer 1113 provided herein enables protection of the adhesive layer 120 from being bombarded and damaged by the plasma.

In addition to being formed between the shunt part 1110 and the sidewall of the first through-hole 111, the filled layer 1113 can cover part of the edge of the shunt part 1110. As shown in FIG. 6, the filled layer 1113 covers the bottom edge of the shunt part 1110 to hold the shunt part 1110; as shown in FIG. 7, the filled layer 1113 coves the top edge of the shunt part 1110. In some embodiments, a first countersink 1115 is formed in the filled layer 1113 above the shunt part 1110. The depth of the first countersink 1115 depends on the distance between the filled layer 1113 above the shunt part and the top of the shunt part 1110. The distance ranges from about 0.1 mm to about 0.3 mm. In this case, the distance between the shunt part 1110 and the disc structure 130 is greater than or equal to the sum of the thickness of the filled layer 1113 above the shunt part 1110 and the depth of the first countersink 1115. In some embodiments, the diameter of the first countersink 1115 is consistent with the diameter of the shunt part 1110 in the horizontal direction. In alternative embodiments, the diameter of the first countersink 1115 is slightly smaller than the diameter of the shunt part 1110 in the horizontal direction.

To further reduce the odds of the cooling gas to incur arcing, a second countersink 1116 is formed on the surface of the disc structure 130 facing towards the first through-hole 111, wherein the shunt part 1110 extends into the second countersink 1116, as shown in FIG. 8. In this way, the interlayer gap 1111 between the disc structure 130 and the shunt part 1110 includes the gap above the shunt part 1110 and the gap located in the sidewall direction of the shunt part 1110, which increases the path length and path sinuosity of the interlayer gap 1111, further reducing the odds of the cooling gas to incur arcing.

In some embodiments, the diameter of the second countersink 1116 is greater than the diameter of the shunt part 1110, wherein the diameter of the second countersink 1116 is consistent with or slightly smaller than the diameter of the first through-hole 111. In some embodiments, the depth of the second hole 1116 is 10-50% of the thickness of the disc structure 130. Referring to FIG. 8, the diameter of the second countersink 1116 is slightly smaller than the diameter of the first through-hole 111; an isolation layer 1114 is formed on the sidewall of the shunt part 1110, and a filled layer 1113 made of a material identical to the adhesive layer 120 is formed between the shunt part 1110 and the sidewall of the first through-hole 111.

In the case that the material of the filled layer 1113 is ceramic and the diameter of the second countersink 1116 is consistent with that of the first through-hole 111, the filled layer 1113 extends into the second countersink 1116, and the distance between the disc structure 130 above the filled layer 1113 and the filled layer 1113 is smaller than the distance between the disc structure 130 above the shunt part 1110 and the shunt part 1110; in the case that the diameter of the second countersink 1116 is smaller than that of the first through-hole 111, the filled layer 1113 does not extend into the second countersink 1116, and the distance between the disc structure 130 above the filled layer 1113 and the filled layer 1113 is smaller than the distance between the disc structure 130 above the shunt part 1110 and the shunt part 1110.

Embodiments of the present disclosure provide an electrostatic chuck, comprising a base and a disc structure disposed on the base, the upper surface of the disc structure being configured to hold a wafer. A first through-hole is formed in the base. A shunt part is formed in the first through-hole, the shunt part partitioning the first through-hole into a plurality of sub-through-holes. A filled layer is formed between the shunt part and the sidewall of the first through-hole. A second through-hole is provided in and axially penetrating through the disc structure, the first through-hole communicating with the second through-hole. Such configurations enable a cooling gas to pass through the plurality of sub-through-holes in the first through-hole towards the second through-hole so as to access the wafer held on the disc structure, thereby regulating wafer temperature; while the filled layer is configurable to fill up the sidewall gap between the shunt part and the base, which avoids the cooling gas in the first through-hole and the second through-hole from accessing the sidewall gap, thereby reducing the discharge space for the cooling gas, lowering the odds of breaking down the cooling gas, and enhancing service life of the electrostatic chuck.

In the embodiments above, the odds of breaking down the cooling gas is lowered by reducing the discharge space in the first through-hole, thereby increasing the service life of the electrostatic chuck. In alternative embodiments, the odds of breaking down the cooling gas is further lowered by reducing the discharge space in the second through-hole, which further improves service life of the electrostatic chuck.

In some embodiments, the second through-hole 131 includes a plurality of sub-through-holes 1311, such that the discharge space for the cooling gas in the second through-hole 131 is partitioned into a plurality of smaller spaces, which significantly lowers the odds of the cooling gas to incur arcing in the second through-hole 131. The sub-through-holes 1311 in the second through-hole 131 are optionally straight passageways, or curved passageways, or annular through-holes, or of other shapes. The sub-through-holes 1311 are optionally uniformly distributed or non-uniformly distributed. The diameter of the sub-through-holes 1311 of the second through-hole is smaller than that of the second through-hole 131, such that with more sub-through-holes 1311 arranged in the second through-hole 131, the same gas flow as the second through-hole 131 is achieved. For example, the diameter of the second through-hole 131 ranges from 0.3 mm to 0.5 mm, and the diameter of the second sub-through-holes 1311 is optionally 0.05 mm, 0.08 mm, 0.1 mm, 0.12 mm, etc.; in the case that the second through-hole 131 is an circular through-hole with a diameter of 0.3 mm, 9 circular sub-through-holes 1311 with a diameter of 0.1 mm are correspondingly arranged to achieve the same gas flow.

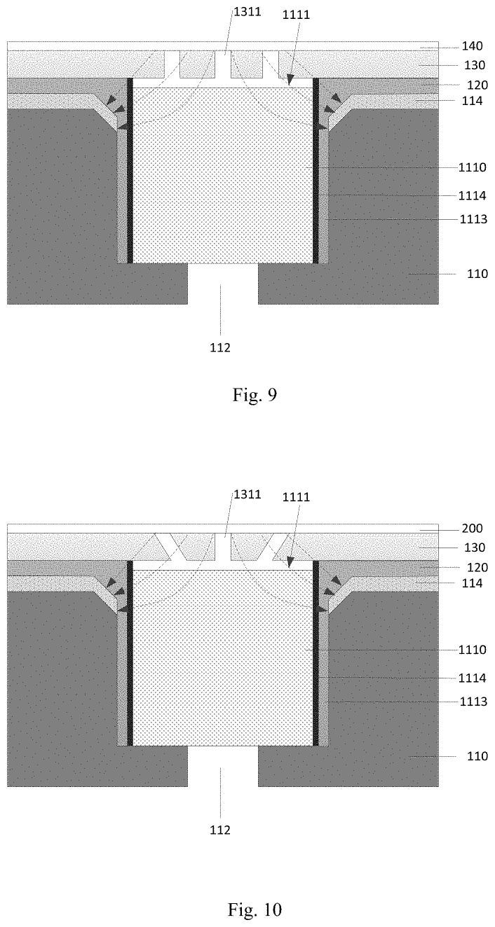

It is noted that in the presence of wafer 200 held on the electrostatic chuck, the wafer 200 is disposed above the second through-hole 131, while the underneath of the second through-hole 131 exactly faces the first through-hole 111. The wafer 200 at this position is relatively distant from the base 110, such that the direction of electric field lines between the wafer 200 and the base 110 points from the wafer 200 to the sidewall of the first through-hole 111 in the base 110, as shown in FIG. 2 and FIG. 9, where the dotted-line direction indicates the direction of electric field lines, wherein the closer the electric field line direction between the wafer 200 and the base 110 is to the central position of the second through-hole 131, the closer the electric field line direction in the second through-hole 131 is to the vertical direction of the wafer 200.

The odds of the cooling gas to incur arcing in the second through-hole 131 is related to the odds of collision between excited electrons and cooling gas molecules. The larger the odds of collision between the electrons and the cooling gas molecules in the second through-hole 131 is, the larger is the odds of arcing occurrence in the second through-hole 131. Studies show that the odds of collision between the electrons and the cooling gas molecules in the second through-hole 131 is associated with the mean free path of the cooling gas.

Referring to FIG. 2, where the second through-hole 131 has a diameter of 0.3 mm and a depth of 1 mm, under He pressure of 20 Torr, when the electric field direction is parallel to the wafer direction, the number of times of collisions between electrons and He atoms approximates to 0.3 mm/6.6 μm=45 times; when the electric field direction is vertical to the wafer direction, the number of times of collisions between electrons and He atoms approximates to 1 mm/6.6 μm=152 times.

Referring to FIG. 9, where the sub-through-holes 1311 of the second through-hole have a diameter of 0.1 mm and a depth of 1 mm; under He pressure of 20 Torr, in the case that the electric field direction is parallel to the wafer direction, the number of times of collisions between electrons and He atoms approximates to 0.1 mm/6.6 μm=15 times; in the case that the electric field direction is vertical to the wafer direction, the number of times of collisions between electrons and He atoms approximates to 1 mm/6.6 μm=152 times.

In other words, compared with the scenario where one second through-hole 131 in FIG. 2 is provided, providing more sub-through-holes 1311 in the second through-hole 131 in FIG. 9 reduces the number of times of collisions between electrons and He atoms, thereby lowering the odds of the cooling gas to create arcing in the second through-hole 131.

In practice, in the second through-hole 131 and the sub-through-holes 1311 of the second through-hole, few electric fields are parallel/vertical to the wafer direction, and most of the electric field directions have an included angle with the wafer direction. Supposing that the included angle between the electric field direction and the wafer direction is θ, then when a sub-through-hole 1311 of the second through-hole is arranged vertical to the wafer direction (as shown in FIG. 9), the diameter of the discharge space in the sub-through-hole 1311 is actually the distance along the electric field line direction, and then the diameter of the discharge space is the ratio of its horizontal diameter to cos θ. Supposing that θ is 45°, for a sub-through-hole with a diameter of 0.1 mm, under He pressure of 20 Torr, the number of collisions between the electrons and He atoms is (0.1 mm/cos 45°)/6.6 um=21 times, far less than 45 times and 152 times of collisions in the single second through-hole of 0.3 mm, which significantly reduces the number of times of collisions between the electrons and He atoms and lowers the odds of the cooling gas to incur arcing in the second through-hole 131.

Based on the configurations above, in some embodiments of the present disclosure, the odds of the cooling gas to incur arcing in the sub-through-hole 1311 is further lowered by changing the direction of the sub-through-hole 1311 in the second through-hole 131. In some embodiments, the directions of the sub-through-holes 1311 in the second through-hole which are not located in the center of the second through-hole are vertical to the electric field line direction, as shown in FIG. 10; as such, the directions of the discharge spaces for the sub-through-holes 1311 of the second through-hole are vertical to the inner wall direction of the sub-through-holes 1311, i.e., the diameters of the discharge spaces are consistent with the inner diameters of the sub-through-holes 1311. For a sub-through-hole with a diameter of 0.1 mm, the number of times of collisions between electrons and He atoms is 0.1 mm/6.6 um=15 times under He pressure of 20 Torr, which further reduces the number of times of collisions between electrons and He atoms and lowers the odds of the cooling gas to incur arcing in the second through-hole 131.

In some embodiments, the sub-through-holes 1311 of the second through-hole 131 are obtained directly by etching the disc structure 130. As shown in FIG. 9 and FIG. 10, the discharge space for the cooling gas in the second through-hole 131 is partitioned into smaller spaces in the plurality of sub-through-holes 1311, greatly lowering the odds of the cooling gas to incur arcing in the second through-hole 131.

In some embodiments, the shunt part 1312 is formed in each of the sub-through-holes 1311 of the second through-hole, as shown in FIG. 11; as such, the discharge space for the cooling gas in the sub-through-holes 1311 is further partitioned into a plurality of smaller spaces, significantly lowering the odds of the cooling gas to incur arcing in the second through-hole 131. In some embodiments, the shunt part 1312 fills up the sub-through-holes 1311 of the second through-hole, as shown in FIG. 11; or the shunt part 1312 only takes up partial depth of the sub-through-holes 1311 of the second through-hole (not shown).

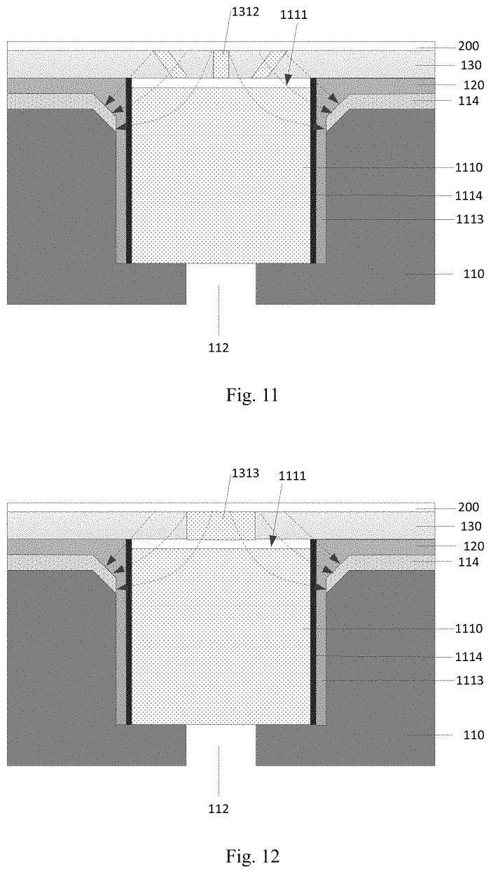

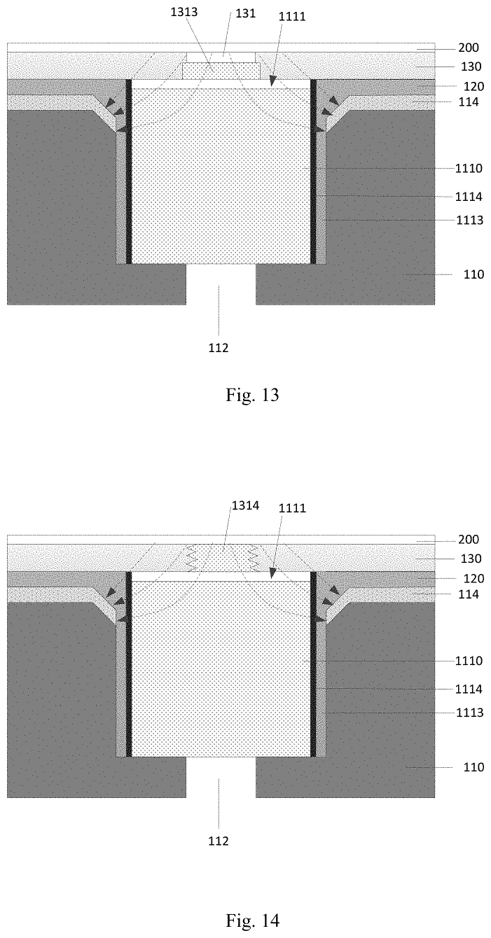

In addition, in the case that the second-through-hole 131 is a single through-hole, a shunt part 1313 is optionally further formed in the second through-hole 131, wherein the shunt part 1313 fills up the second through-hole 131, as shown in FIG. 12; the shunt part 1313 optionally only takes up partial depth of the second through-hole 131, as shown in FIG. 13, wherein the diameter of the upper portion of the second through-hole 131 is smaller than that of the lower portion thereof, and the shunt part 1313 is formed at the lower portion of the second through-hole 131 to partition the lower portion of the second through-hole 131 into a plurality of sub-through-holes.

Additionally, in the case that the second through-hole 131 is a single through-hole, the sidewall of the second through-hole 131 is configurable to have an uneven surface, for example, a threaded profile, as shown in FIG. 14; as such, the gas flows along the threaded structure, which reduces the discharge space without affecting the gas flow. Of course, in some embodiments, a shunt structure 1314 is provided in the second through-hole 131, and the outer wall of the shunt structure 1314 is threaded to correspond to the inner wall of the second through-hole 131 so as to be threaded into the second through-hole 131.

The embodiments of the present disclosure enable further reduction of the odds of breaking down the cooling gas by reducing the discharge space in the second through-hole, thereby further improving service life of the electrostatic chuck.

FIG. 1 shows a sectional structural schematic diagram of a plasma processing apparatus provided according to the embodiments of the present disclosure, wherein the plasma processing apparatus comprises: an upper electrode 400 and an electrostatic chuck 100, wherein the electrostatic chuck 100 refers to corresponding depictions in the embodiments above, which will not be detailed here.

In some embodiments, the plasma processing apparatus further comprises, inter alia, a focus ring surrounding the wafer 200 held on the electrostatic chuck 100, and an isolation ring surrounding the base 110. In a capacitively coupled plasma (CCP) etching chamber, the upper electrode 400 optionally refers to a gas showerhead, above which is further provided a mounting substrate, wherein the gas showerhead is fixedly connected to a top cover 9 of the reaction chamber via the mounting substrate; an inductively coupled plasma (ICP) etching chamber optionally further comprises a dielectric window provided above the sidewall of the reaction chamber, an inductively coupled coil disposed above the dielectric window, and a gas inlet disposed at one end of the reaction chamber sidewall proximal to the dielectric window, wherein a reactive gas enters the vacuum reaction chamber via the gas inlet. The inductively coupled coil generates a strong high-frequency alternating magnetic field, ionizing the low-pressure reactive gas to generate plasma.

In alternative embodiments, the plasma processing apparatus further comprises other components that are configurable by those skilled in the art based on actual needs, which are thus not illustrated with examples one by one.

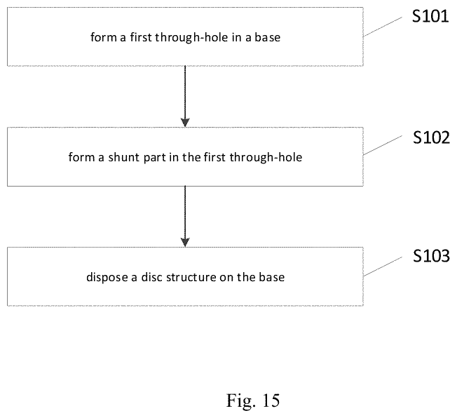

Based on the electrostatic chuck described above, embodiments of the present disclosure further provide a method of manufacturing an electrostatic chuck. FIG. 15 is a flow diagram of the method of manufacturing an electrostatic chuck according to the embodiments of the present disclosure. In some embodiments, the method comprises steps of:

S101: forming a first through-hole in a base.

In some embodiments, the base is made of a metal material, e.g., aluminum, stainless steel, and etc. In some embodiments, the first through-hole is obtained by etching the formed base; or, a base with a first through-hole is formed during fabrication of the base. In alternative embodiments, a plurality of first through-holes are provided. A chamfering is formed at the top opening of the first through-hole, and a dielectric layer is optionally fabricated on the upper surface of the base where the first through-hole is not formed, the dielectric layer covering the chamfering at the top opening of the first through-hole.

S102: forming a shunt part in the first through-hole.

In some embodiments, the shunt part partitions the first through-hole into a plurality of sub-through-holes. Optionally, the shunt part refers to a porous plug.

In some embodiments of the present disclosure, the forming a shunt part in the first through-hole is implemented in the following two manners:

First Manner: the shunt part whose sidewall is surrounded by an isolation layer is inserted into the first through-hole, and a filling material is injected between the shunt part and the sidewall of the first through-hole to form a filled layer between the isolation layer and the sidewall of the first through-hole; meanwhile an adhesive layer between the base and the disc structure is fabricated with the filling material; the adhesive layer is formed at a position in the base where the first-through-hole is not formed; and the adhesive layer is configurable for bonding the base and the disc structure.

Second Manner: the shunt part is disposed in the filled layer, wherein the material for the filled layer is selected from at least one of ceramics, epoxy, and silicon resin; the filled layer enclosing the shunt part is disposed in the first through-hole, wherein the filled layer reduces the distance between the shunt part and the sidewall of the first through-hole.

Optionally, the filled layer covers the upper edge and/or lower edge of the shunt part.

Optionally, a first countersink is formed in a surface of the filled layer covering the upper edge of the shunt part, the surface of the filled layer facing towards the first through-hole.

Optionally, an interlayer gap is provided between the shunt structure and the disc structure, the distance between the filled layer and the disc structure being smaller than the interlayer gap.

Optionally, a second countersink is formed in a surface of the disc structure, the surface of the disc structure facing towards the base, and the shunt part extending into the second countersink.

S103: disposing the disc structure on the base.

The upper surface of the disc structure is configured to hold the wafer; a second through-hole is provided in and axially penetrating through the disc structure, wherein the second through-hole communicates with the first through-hole.

Optionally, the second through-hole comprises a plurality of sub-through-holes.

Optionally, the plurality of sub-through-holes are formed by fabricating a porous structure in the second through-hole, or are formed by etching the disc structure.

Optionally, after the base is powered up, an electric field line is present between the wafer on the disc structure and the base, the directions of the plurality of sub-through-holes not located in the center of the second through-hole being vertical to the direction of the electric field line.

What have been described above are only preferred embodiments of the present disclosure; despite of those preferred embodiments disclosed above, the present disclosure is not limited thereto. Any technical person in the art may make various possible alterations and modifications to the technical solutions of the present disclosure or modify them into equivalent varied embodiments using the methods and technical contents described above without departing from the scope of the technical solutions of the present disclosure. Therefore, any content without departing from the technical solutions of the present disclosure and any simple alteration, equivalent variation and modification to those embodiments based on the technical substance of the present disclosure still fall within the protection scope of the technical solutions of the present disclosure.

I/we claim:

1. An electrostatic chuck, comprising:
a base, wherein a first through-hole is formed in the base, a shunt part is provided in the first through-hole to partition the first through-hole into a plurality of sub-through-holes, and a filled layer is formed between the shunt part and a sidewall of the first through-hole; and
a disc structure disposed on the base, wherein an upper surface of the disc structure is configured to hold the wafer, and a second through-hole is provided in and axially penetrating through the disc structure, the second through-hole communicating with the first through-hole.

2. The electrostatic chuck according to claim 1, wherein the filled layer is made of a material selected from at least one of ceramic, epoxy, and silicon resin.

3. The electrostatic chuck according to claim 2, wherein the filled layer covers the upper edge and/or lower edge of the shunt part.

4. The electrostatic chuck according to claim 3, wherein a first countersink is formed in a surface of the filled layer covering the upper edge of the shunt part, the surface of the filled layer facing towards the first through-hole.

5. The electrostatic chuck according to claim 3, wherein the disc structure and the base are bonded via an adhesive layer, the filled layer and the adhesive layer being made of a same material, an isolation layer being formed between the shunt part and the filled layer.

6. The electrostatic chuck according to claim 1, wherein an interlayer gap is provided between the shunt structure and the disc structure, the distance between the filled layer and the disc structure being smaller than the interlayer gap.

7. The electrostatic chuck according to claim 1, wherein a second countersink is formed in a surface of the disc structure, the surface of the disc structure facing towards the base, and the shunt part extending into the second countersink.

8. The electrostatic chuck according to claim 1, wherein the second through-hole comprises a plurality of sub-through-holes.

9. The electrostatic chuck according to claim 8, wherein the plurality of sub-through-holes are formed by fabricating a porous structure in the second through-hole, or are formed by etching the disc structure.

10. The electrostatic chuck according to claim 8, wherein after the base is powered up, an electric field line is present between the wafer on the disc structure and the base, and the directions of the plurality of sub-through-holes not located in the center of the second through-hole are vertical to the direction of the electric field line.

11. The electrostatic chuck according to claim 1, wherein a chamfering is formed at the upper opening of the first through-hole, and a dielectric layer is provided between the base and the adhesive layer bonding the base and the disc structure, the dielectric layer covering the chambering.

12. The electrostatic chuck according to claim 1, wherein the shunt structure refers to a porous plug.

13. A method of manufacturing an electrostatic chuck, comprising:
forming a first through-hole in a base;
forming a shunt part in the first through-hole to partition the first through-hole into a plurality of sub-through-holes, a filled layer being formed between the shunt part and a sidewall of the first through-hole; and
providing a disc structure on the base, wherein an upper surface of the disc structure is configured to hold the wafer; and a second through-hole is provided in and axially penetrating through the disc structure, the second through-hole communicating with the first through-hole.

14. The method according to claim 13, wherein the forming a shunt part in the first through-hole comprises:
disposing the shunt part in the first through-hole, an isolation layer being formed on the outer wall of the shunt part;
filling up between the shunt part and the sidewall of the first through-hole to form the filled layer, and forming an adhesive layer at a position of the base where the first through-hole is not formed, the adhesive layer being configured to bond the base and the disc structure, the filled material and the adhesive layer being made of a same material.

15. The method according to claim 13, wherein the forming a shunt part in the first through-hole comprises:
disposing the shunt part in the filled layer, wherein the filled layer is made of a material selected from at least one of ceramic, epoxy, and silicon resin; and
disposing, in the first through-hole, the filled layer enclosing the shunt part.

16. A plasma processing apparatus, comprising an upper electrode and the electrostatic chuck according to claim 1.
